(19) United States
(12) Patent Application Publication
(10) Pub. No.: US 2025/0022953 A1
(43) Pub. Date: Jan. 16, 2025

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventor: Takafumi UCHIDA, Matsumoto-city (JP)

(73) Assignee: FUJI ELECTRIC CO., LTD., Kawasaki-shi (JP)

(21) Appl. No.: 18/903,363

(22) Filed: Oct. 1, 2024

Related U.S. Application Data
(63) Continuation of application No. PCT/JP2023/031087, filed on Aug. 29, 2023.

(30) Foreign Application Priority Data
Oct. 6, 2022 (JP) 2022-161809

(51) Int. Cl. H01L 29/78; H01L 21/66; H01L 29/06; H01L 29/16; H01L 29/66

(52) U.S. Cl. CPC H01L 29/7813; H01L 22/12; H01L 22/24; H01L 29/0623; H01L 29/0684; H01L 29/1608; H01L 29/66712

(57) ABSTRACT

A method of manufacturing a vertical silicon carbide semiconductor device having an electrode on each of two main surfaces of a semiconductor chip in which an n-type low concentration buffer layer and an epitaxial layer are grown by epitaxy on a silicon carbide substrate. Defects extending from the silicon carbide substrate to the epitaxial layer and defects generated in the epitaxial layer during epitaxial growth are detected by a PL image of the n-type low concentration buffer layer; the defects generated in the epitaxial layer during the epitaxy are detected by a PL image of the epitaxial layer; the defects extending from the silicon carbide substrate to the epitaxial layer are detected by the difference between detection results; and semiconductor chips free of the defects extending from the silicon carbide substrate to the epitaxial layer are identified.

### CROSS REFERENCE TO RELATED APPLICATIONS

This is a continuation application of International Application PCT/JP2023/031087 filed on Aug. 29, 2023 which claims priority from a Japanese Patent Application No. 2022-161809 filed on Oct. 6, 2022, the contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

Conventionally, in a metal oxide semiconductor field effect transistor (SiC-MOSFET: a MOS-type field effect transistor with an insulated gate having a three-layer structure of metal-oxide-semiconductor) containing silicon carbide (SIC) as a semiconductor material, semiconductor chips are used, which are formed by epitaxially growing epitaxial layers constituting an n-type drift region and a p-type base region sequentially on an n⁺-type starting substrate containing silicon carbide. Basal plane dislocations (BPDs) occur in the epitaxial layers of the semiconductor chips due to propagation (expansion) from the starting substrate or process damage during epitaxial growth.

In the epitaxial layers, when a parasitic diode (body diode) formed by a pn junction between the p-type base region and the n⁻-type drift region conducts, minority carriers (holes) injected into the n-type drift region due to bipolar operation of the body diode recombine with electrons. When this recombination occurs near a BPD, Shockley-type stacking faults grow (expand) in the epitaxial layers starting from the BPD, degrading forward characteristics of the body diode and on-voltage characteristics of the MOSFET. Therefore, by arranging an n⁺-type buffer layer 101 (epitaxial layer) between the starting substrate (n⁺-type silicon carbide substrate 101) and an n-type silicon carbide epitaxial layer 102, the number of holes reaching the BPD from the pn junction is reduced to suppress growth of Shockley-type stacking faults (refer to FIG. 7).

A method of manufacturing a SiC device is known (refer to, for example, Japanese Laid-Open Patent Publication No. 2020-13939) which may easily detect defects generated during processing, the method including a surface inspection step of inspecting a surface of an SiC epitaxial wafer, a PL inspection step of irradiating the surface of the SiC epitaxial wafer with an excitation light to measure photoluminescence, and a step of determining the degree of defects from an image of a surface defect detected in the surface inspection and an image of a PL defect detected in the PL inspection step.

A defect inspection method is known in which a basal plane dislocation that is in a buffer layer and converted into a threading edge dislocation (TED) can be easily detected by a PL inspection, the method including: a first irradiation step (S1) of irradiating the entire silicon carbide substrate with a first ultraviolet light; a second irradiation step (S4) of irradiating a candidate region of the silicon carbide substrate with a second ultraviolet light at a higher intensity than the first excitation light; and a third irradiation step (S6) of irradiating the silicon carbide substrate with a third ultraviolet light at a lower intensity than the second ultraviolet light (refer to, for example, Japanese Patent No. 6999212).

### SUMMARY OF THE INVENTION

According to an embodiment of the present invention, a vertical silicon carbide semiconductor device formed in a semiconductor chip having two main surfaces opposite to each other, includes: a silicon carbide substrate; a buffer layer that is an epitaxial layer on the silicon carbide substrate: another epitaxial layer having a doping concentration in a range of 1×10¹⁵/cm³ to 1×10¹⁶/cm³ on the buffer layer; and electrodes on each of the two main surfaces of the semiconductor chip. The buffer layer has a doping concentration that is higher than the doping concentration of the another epitaxial layer but not more than 3×10¹⁷/cm³. The silicon carbide semiconductor device is free of a defect that extends from the silicon carbide substrate to the another epitaxial layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor wafer on which a silicon carbide semiconductor device according to an embodiment is manufactured (fabricated), is viewed from a front side thereof.

FIG. 2 is a cross-sectional view depicting a structure of the silicon carbide semiconductor device according to the embodiment.

FIG. 3 is a flowchart depicting an outline of a method of manufacturing the silicon carbide semiconductor device according to the embodiment.

FIG. 4 is a cross-sectional view depicting defect detection from a PL image of an n-type low concentration buffer layer in the method of manufacturing the silicon carbide semiconductor device according to the embodiment.

FIG. 5 is a cross-sectional view depicting defect detection from a PL image of an n-type silicon carbide epitaxial layer in the method of manufacturing the silicon carbide semiconductor device according to the embodiment.

FIG. 6 is a cross-sectional view depicting another structure of the silicon carbide semiconductor device according to the embodiment.

FIG. 7 is a cross-sectional view depicting another structure of the silicon carbide semiconductor device according to the embodiment.

FIG. 8 is a cross-sectional view depicting another structure of the silicon carbide semiconductor device according to the embodiment.

FIG. 9 is a cross-sectional view depicting another structure of the silicon carbide semiconductor device according to the embodiment.

FIG. 10 is a cross-sectional view depicting defect detection in a conventional method of manufacturing a silicon carbide semiconductor device.

### DETAILED DESCRIPTION OF THE INVENTION

First, problems associated with the conventional techniques are discussed. Anomalies inside the semiconductor wafer are observed in a photoluminescence (PL) image of a crystal defect inspection system. Poly-type triangular stacking faults can be detected by the PL image. The poly-type triangular stacking faults are killer defects causing a significant decrease in the tolerance, reliability, and electrical characteristics of the silicon carbide semiconductor devices. Therefore, stacking faults are detected by the PL image to remove all chip regions in which poly-type triangular stacking faults are detected as defective chips.

FIG. 10 is a cross-sectional view depicting defect detection in a conventional method of manufacturing a silicon carbide semiconductor device. As depicted in FIG. 10, conventionally, a PL image in an n⁺-type high concentration buffer layer 120 is obtained. The PL image of the n⁺-type high concentration buffer layer 120 can be obtained by irradiating an excitation light 133 that penetrates inside the n⁺-type high concentration buffer layer 120. For example, in cases where the n-type silicon carbide epitaxial layer 102 is about 10 μm, the PL image in the n⁺-type high concentration buffer layer 120 can be obtained by setting the wavelength of the excitation light (irradiation light) to 313 nm when obtaining the PL image. This PL image can detect defects 131 from the n⁺-type silicon carbide substrate 101 and defects 132 from the n-type silicon carbide epitaxial layer 102. The defects 131 from the n⁺-type silicon carbide substrate 101 are known to be killer defects while the defects 132 from the n⁻-type silicon carbide epitaxial layer 102 are known not to be killer defects.

The conventional method, however, cannot distinguish between the defects 131 from the n⁺-type silicon carbide substrate 101 and the defects 132 from the n⁻-type silicon carbide epitaxial layer 102 to remove chip regions containing only the defects 132 from the n⁻-type silicon carbide epitaxial layer 102 as defective chips. This causes a problem in that a rate of conforming products decreases.

In light of these problems, a silicon carbide semiconductor device according to the present invention has the following features. A vertical silicon carbide semiconductor device includes electrodes on each of two main surfaces of a semiconductor chip in which a low concentration buffer layer and an epitaxial layer having a doping concentration in a range of 1×10¹⁵/cm³ to 1×10¹⁶/cm³ are grown on a silicon carbide substrate by epitaxy. The low concentration buffer layer has a doping concentration that is higher than the doping concentration of the epitaxial layer but not more than 3×10¹⁷/cm³, and the silicon carbide semiconductor device is free of a defect extending from the silicon carbide substrate to the epitaxial layer.

Further, the silicon carbide semiconductor device above includes a transition layer disposed between the silicon carbide substrate and the epitaxial layer, the transition layer having a doping concentration between the doping concentration of the low concentration buffer layer and a doping concentration of the silicon carbide substrate.

Further, in the silicon carbide semiconductor device above, the transition layer is thinner than the low concentration buffer.

Further, the silicon carbide semiconductor device above includes a high concentration buffer layer disposed between the silicon carbide substrate and the epitaxial layer, the high concentration buffer layer having a doping concentration between the doping concentration of the transition layer and the doping concentration of the silicon carbide substrate.

Further, in the silicon carbide semiconductor device above, the high concentration buffer layer is thicker than the low concentration buffer layer.

Further, in light of the problems above, a silicon carbide semiconductor device according to the present invention has the following features. A vertical silicon carbide semiconductor device includes electrodes on each of two main surfaces of a semiconductor chip in which a low concentration buffer layer and an epitaxial layer having a doping concentration in a range of 1×10¹⁵/cm³ to 1×10¹⁶/cm³ are grown on a silicon carbide substrate by epitaxy. The low concentration buffer layer has a doping concentration that is higher than the doping concentration of the epitaxial layer but not more than 3×10¹⁷/cm³; the silicon carbide semiconductor device is free of a defect extending from the silicon carbide substrate to the epitaxial layer; and the silicon carbide semiconductor device includes a defect generated in the epitaxial layer during the epitaxy.

Further, in the silicon carbide semiconductor device above, the doping concentration of the low concentration buffer layer is not more than 3×10¹⁷/cm³.

Further, in the silicon carbide semiconductor device above, a transition layer disposed between the low concentration buffer layer and the epitaxial layer, the transition layer having a doping concentration that is higher than the doping concentration of the low concentration buffer layer.

Further, in light of the problems above, a method of manufacturing a silicon carbide semiconductor device according to the present invention has the following features. The method is a method of manufacturing a vertical silicon carbide semiconductor device having electrodes on each of two main surfaces of a semiconductor chip in which a low concentration buffer layer and an epitaxial layer are grown on a silicon carbide substrate by epitaxy. A pre-process of preparing a semiconductor wafer in which the low concentration buffer layer and the epitaxial layer are grown on the silicon carbide substrate by epitaxy is performed. Next, a first detecting process of using a PL image of the low concentration buffer layer to detect a first defect extending from the silicon carbide substrate to the epitaxial layer and a second defect generated in the epitaxial layer during the epitaxy is performed. Next, a second detecting process of using a PL image of the epitaxial layer to detect the second defect generated in the epitaxial layer during the epitaxy is performed. Next, a third detecting process of detecting the first defect extending from the silicon carbide substrate to the epitaxial layer based on a difference between detection results of the first detecting process and the second detecting process is performed. Next, a forming process of forming a predetermined device structure in the semiconductor wafer is performed. Next, a cutting process of dicing the semiconductor wafer into a plurality of individual semiconductor chips after the forming process is performed. Next, a selecting process of selecting from the plurality of semiconductor chips, one free of the first defect extending from the silicon carbide substrate to the epitaxial layer, based on a result of the third detecting process.

Further, in the method of manufacturing the silicon carbide semiconductor device above, the first detecting process includes obtaining the PL image of the low concentration buffer layer by setting a confocal position of an excitation light to be inside the low concentration buffer layer, the excitation light being used to obtain the PL image of the low concentration buffer layer, and the second detecting process includes obtaining the PL image of the epitaxial layer by setting the confocal position of the excitation light to be inside the epitaxial layer, the excitation light being used to obtain the PL image of the epitaxial layer.

Further, in the method of manufacturing the silicon carbide semiconductor device above, the first detecting process includes obtaining the PL image of the low concentration buffer layer by adjusting a wavelength of an excitation light used to obtain the PL image of the low concentration buffer layer, and the second detecting process includes obtaining the PL image of the epitaxial layer by adjusting the wavelength of the excitation light used to obtain the PL image of the epitaxial layer, the wavelength being adjusted to be shorter than the wavelength used in the first detecting process.

Embodiments of a silicon carbide semiconductor device and a method of manufacturing a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the doping concentration is higher or lower, respectively, than layers and regions without + or −. In the description of the embodiments below and the accompanying drawings, main portions that are identical are given the same reference numerals and are not repeatedly described. Further, in the present description, when Miller indices are described, “-” means a bar added to an index immediately after the “-”, and a negative index is expressed by prefixing “-” to the index. Further, with consideration of variation in manufacturing, description indicating the same or equal may be within 5%.

A semiconductor device according to the present invention is configured using a wide band gap semiconductor. In an embodiment, a silicon carbide semiconductor device fabricated (manufactured) using, for example, silicon carbide (SiC) as a wide band gap semiconductor is described by taking a trench-type MOSFET 70 as an example.

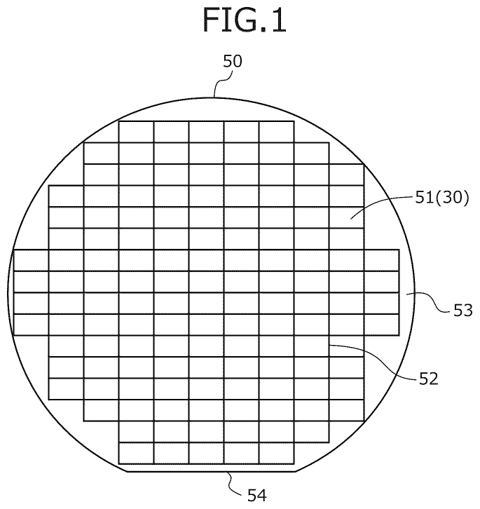

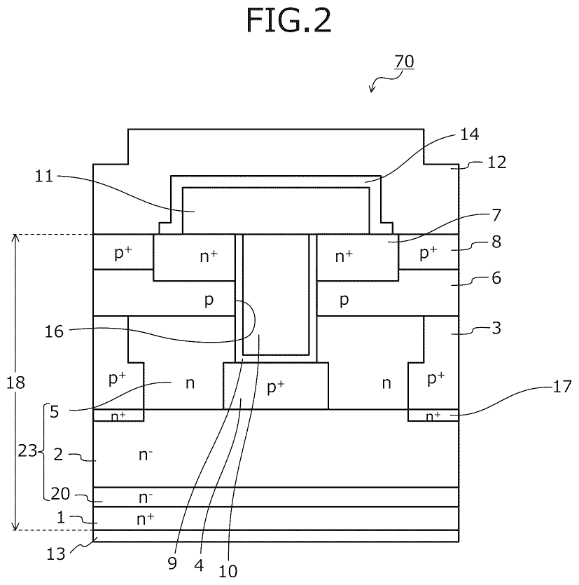

FIG. 1 is a plan view depicting a layout when a semiconductor wafer on which the silicon carbide semiconductor device according to the embodiment is manufactured (fabricated), is viewed from a front side thereof. FIG. 2 is a cross-sectional view depicting a structure of the silicon carbide semiconductor device according to the embodiment. FIG. 2 depicts only an active region through which a main current of the trench-type MOSFET 70 flows.

As depicted in FIG. 1, a semiconductor wafer 50 may have, for example, an orientation flat (a linear notch provided at a portion of an edge) 54 or a notch (a V-shaped notch provided at a portion of an edge: not depicted) indicating the surface orientation. Each chip region 51 of the semiconductor wafer 50 is cut (diced) along dicing lines 52 and is thereby divided into individual semiconductor chips 30. All the semiconductor chips 30 divided from the same semiconductor wafer 50 have a same silicon carbide semiconductor substrate 18 (refer to FIG. 2) and have a same device structure (here, a trench gate structure: refer to FIG. 2) formed in the same process.

The chip region 51 has a substantially rectangular shape in a plan view and is one of multiple chip regions 51 arranged in a matrix-like pattern in substantially a center of the semiconductor wafer 50. Adjacent ones of the chip regions 51 are arranged to share, for example, one side. The dicing lines 52 are formed at the boundary between the adjacent ones of the chip regions 51. The dicing lines 52 surround the chip regions 51 in a lattice-like pattern. The dicing lines 52 are grooves formed on a main surface of the semiconductor wafer 50 (surface of the silicon carbide semiconductor substrate 18 in FIG. 2). In the dicing lines 52, a mark (a position specifying mark: not depicted) is formed for specifying positions (coordinates) in a direction parallel to the surface of the semiconductor wafer 50.

The position specifying mark is an indicator for specifying positions of each chip region 51 and positions of crystal defects. The position specifying mark is, for example, a convex or concave portion having a predetermined shape in a plan view (e.g., a cross shape), formed by etching in the dicing lines 52. The position specifying mark may be provided in an non-operating region 53 of the semiconductor wafer 50. The non-operating region 53 is a portion of the semiconductor wafer 50 between an outermost one of the chip regions 51 and the end of the semiconductor wafer 50 and is not used as the semiconductor chips 30. As the position specifying mark, an alignment mark for positioning (aligning) components of the device structure formed in the chip region 51 may be used.

The silicon carbide semiconductor device according to the embodiment depicted in FIG. 2 is, for example, an n-channel trench-type MOSFET 70 having, in an active region, a trench gate structure at a front surface of the semiconductor chip 30, which contains silicon carbide. The active region is a region through which the main current (drift current) flows when the trench-type MOSFET 70 is in an on-state, and multiple unit cells (functional units of a device) of the trench-type MOSFET 70 each having the same structure are arranged adjacent to one another. FIG. 2 depicts one unit cell of the trench-type MOSFET 70. The active region is arranged, for example, in substantially the center (chip center) of the semiconductor chip 30 and is surrounded by an edge termination region.

The edge termination region is a region between the active region and the end (chip end) of the semiconductor chip 30. The edge termination region has a function of maintaining a breakdown voltage by mitigating the electric field of the front surface of the semiconductor chip 30. The breakdown voltage is a voltage limit at which leakage current does not increase excessively and the silicon carbide semiconductor device does not malfunction or break down.

As depicted in FIG. 2, the silicon carbide semiconductor device according to the embodiment is configured using the silicon carbide semiconductor substrate 18 formed by sequentially stacking an n-type low concentration buffer layer (buffer first layer) 20, an n-type silicon carbide epitaxial layer (epitaxial layer) 2, and a p-type base layer 6 on a first main surface (front surface), for example, a (0001) surface (Si surface), of an n⁺-type silicon carbide substrate (silicon carbide substrate) 1 having a doping concentration of 5×10¹⁸/cm³ or higher. The n-type low concentration buffer layer 20 has a doping concentration at least three times higher than a doping concentration of the n′type silicon carbide epitaxial layer 2.

An n⁺-type high concentration region 5 may be provided on a first surface of the n⁻-type silicon carbide epitaxial layer 2, the first surface being opposite to a second surface of the n⁻-type silicon carbide epitaxial layer 2 facing the n⁺-type silicon carbide substrate 1. The n⁻-type high concentration region 5 is a high concentration n-type drift layer with a doping concentration lower than a doping concentration of the n⁺-type silicon carbide substrate 1 and higher than a doping concentration of the n⁻-type silicon carbide epitaxial layer 2. The n-type silicon carbide epitaxial layer 2 has a doping concentration, for example, in a range of 1×10¹⁵/cm³ to 1×10¹⁶/cm³, and has a thickness of, for example, 10 μm or more.

The doping concentration of the n⁻-type low concentration buffer layer 20 is, for example, 3×10¹⁷/cm³ or less and is in a range of more than three times the doping concentration of the n⁻-type silicon carbide epitaxial layer 2. When the doping concentration is higher than 3×10¹⁷/cm³ with an excitation light for PL measurement, triangular poly-type stacking faults (hereinafter, simply referred to as defects) cannot be detected, so the doping concentration is set to be not more than 3×10¹⁷/cm³. The thickness of the n⁻-type low concentration buffer layer 20 is preferably, for example, more than 1 μm but not more than about 3 μm. An n-type epitaxial layer 23 includes the n-type silicon carbide epitaxial layer 2 and the n⁻-type low concentration buffer layer 20, and also includes the n-type high concentration region 5 in an instance in which the n-type high concentration region 5 is provided.

A back surface electrode 13 constituting a drain electrode is provided on a second main surface (a back surface, i.e., a back of the silicon carbide semiconductor substrate 18) of the n⁺-type silicon carbide substrate 1.

A trench structure is formed in the silicon carbide semiconductor substrate 18, at the first main surface (p-type base layer 6 side). Specifically, trenches 16 penetrate through the p-type base layer 6 into the n-type high concentration region 5 (or the n-type silicon carbide epitaxial layer 2, when the n-type high concentration region 5 is not provided, hereinafter, simply referred to as “(2)”), from a first surface of the p-type base layer 6, opposite to a second surface of the p-type base layer 6 facing the n⁺-type silicon carbide substrate 1 (the first main surface of the silicon carbide semiconductor substrate 18). Along an inner wall of each of the trenches 16, a gate insulating film 9 is formed on a bottom and sidewalls of the trench 16 and a gate electrode 10 is formed on the gate insulating film 9 in the trench 16. The gate electrode 10 is insulated from the n-type high concentration region 5(2) and the p-type base layer 6 by the gate insulating film 9. A portion of the gate electrode 10 may protrude toward a source electrode 12, from the upper side of each of the trenches 16 (the side facing the source electrode 12 described below).

Between the trenches 16, first p⁺-type base regions 3 are provided in the n-type high concentration region 5(2), at a first surface (the first main surface of the silicon carbide semiconductor substrate 18) of the n-type high concentration region 5(2), the first surface being opposite to a second surface of the n-type high concentration region 5(2) facing the n⁺-type silicon carbide substrate 1. Second p⁺-type base regions 4 at the bottoms of the trenches 16 are provided in the n-type high concentration region 5(2). The second p⁺-type base regions 4 are provided at positions facing the bottoms of the trenches 16 in a depth direction (direction from the source electrode 12 to the drain electrode 13). A width of each of the second p⁺-type base regions 4 is a same as or wider than a width of each of the trenches 16. The bottoms of the trenches 16 may reach the second p⁺-type base regions 4 or may be located in the n-type high concentration region 5(2), between the p-type base layer 6 and the second p⁺-type base regions 4.

In the n-type silicon carbide epitaxial layer 2, n⁺-type regions 17 having a higher peak doping concentration than the n-type high concentration region 5(2) is provided at a deeper position than are the first p⁺-type base regions 3 between the trenches 16. The deeper position refers to a position closer to the back electrode 13 than are the first p⁺-type base regions 3.

In the p-type base layer 6, n⁺-type source regions 7 are selectively provided at the first main surface of the silicon carbide semiconductor substrate 18. Further, p⁺-type contact regions 8 may be selectively provided. The n⁺-type source regions 7 and the p⁺-type contact regions 8 are in contact with each other.

An interlayer insulating film 11 is provided in an entire area of the first main surface of the silicon carbide semiconductor substrate 18 so as to cover the gate electrodes 10 embedded in the trenches 16. The source electrode 12 is in contact with the n⁺-type source regions 7 and the p-type base layer 6 through contact holes opened in the interlayer insulating film 11. In an instance in which the p⁺-type contact regions 8 are provided, the source electrode 12 is in contact with the n⁺-type source regions 7 and the p⁺-type contact regions 8. The source electrode 12 is electrically insulated from the gate electrode 10 by the interlayer insulating film 11. A source electrode pad (not depicted) is provided on the source electrode 12. A barrier metal 14 containing titanium or titanium nitride may be provided between the source electrode 12 and the interlayer insulating film 11, for example, to prevent diffusion of metal atoms from the source electrode 12 to the gate electrode 10.

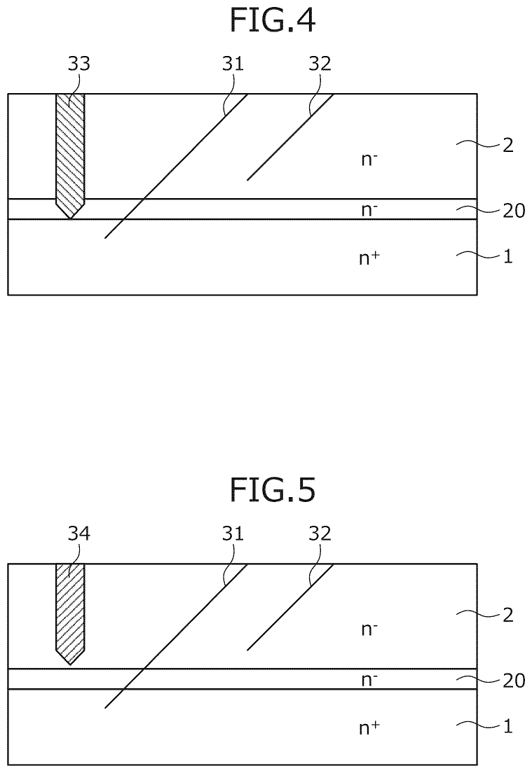

As described in detail below, the silicon carbide semiconductor device according to the embodiment obtains PL images two or more times to separate and detect a killer defect, that is, a defect (first defect) 31 extending from the n⁺-type silicon carbide substrate 1 to the n-type silicon carbide epitaxial layer 2 (hereinafter referred to as the defect 31 from the n⁺-type silicon carbide substrate 1) and a defect (second defect) 32 that is a defect related to epitaxy growth and is generated in n-type silicon carbide epitaxial layer 2 during epitaxial growth (hereinafter referred to as the defect 32 from the n⁻-type silicon carbide epitaxial layer 2), and to classify only semiconductor chips with the defect 31 from the n⁺-type silicon carbide substrate 1 as defective. Refer to FIGS. 4 and 5 for the defects 31 and 32. In an instance in which the n-type high concentration region 5 is provided, defects generated in the n-type high concentration region 5 during epitaxial growth are present.

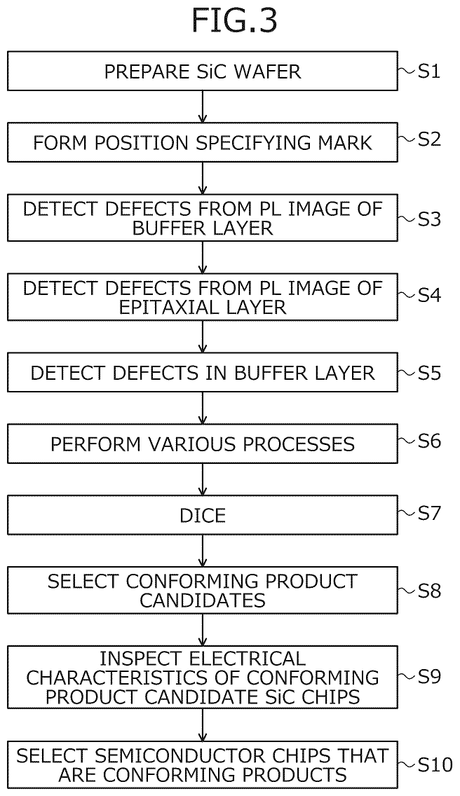

A method of manufacturing the silicon carbide semiconductor device according to the embodiment is described. FIG. 3 is a flowchart depicting an outline of the method of manufacturing the silicon carbide semiconductor device according to the embodiment.

First, the semiconductor wafer (SiC wafer) 50 containing silicon carbide as a semiconductor material is prepared (step S1: pre-process). The semiconductor wafer 50 is formed by epitaxially growing an epitaxial layer (corresponds to the n-type epitaxial layer 23 in FIG. 2) on a starting wafer (corresponds to the n⁺-type silicon carbide substrate 1 in FIG. 2) containing silicon carbide. In the process at step S1, the starting wafer containing silicon carbide may be prepared to fabricate the semiconductor wafer 50, or the semiconductor wafer 50 itself may be purchased. Next, a position specifying mark (not depicted) is formed on the main surface (the surface of the n-type epitaxial layer 23) of the semiconductor wafer 50 (step S2).

In the process at step S2, the position specifying mark (not depicted) is formed on the main surface of the semiconductor wafer 50 in the dicing lines 52 by photolithography and etching. The position specifying mark serves as a reference for specifying positions (coordinates in a direction parallel to the wafer surface) of crystal defects in the semiconductor wafer 50.

Next, by a PL image of the n-type low concentration buffer layer 20 of the semiconductor wafer 50 obtained by a crystal defect inspection system, the size (length, surface area, etc.) and position information of defects (poly-type triangular stacking faults) in the n-type silicon carbide epitaxial layer 2 and the n-type low concentration buffer layer 20 are detected (step S3: first detecting process). In the process at step S3, the PL image of the n-type low concentration buffer layer 20 can be obtained by irradiating an excitation light 33 that penetrates inside the n-type low concentration buffer layer 20, and the size and position information of the defects can be obtained based on the position specifying mark.

FIG. 4 is a cross-sectional view depicting defect detection from the PL image of the n-type low concentration buffer layer in the method of manufacturing the silicon carbide semiconductor device according to the embodiment. As depicted in FIG. 4, at step S3, defects are detected from the n-type low concentration buffer layer 20 to the n⁻-type silicon carbide epitaxial layer 2 using the excitation light 33 that penetrates inside the n⁻-type low concentration buffer layer 20. Therefore, both the defect 32 from the n-type silicon carbide epitaxial layer 2 and the defect 31 from the n⁺-type silicon carbide substrate 1 are detected.

Next, the size (length, surface area, etc.) and position information of defects in the n⁻-type silicon carbide epitaxial layer 2 are detected by the PL image of the n⁻-type silicon carbide epitaxial layer 2 of the semiconductor wafer 50 obtained by the crystal defect inspection system (step S4: second detecting process). In the process at step S4, the PL image of the n⁻-type silicon carbide epitaxial layer 2 can be obtained by irradiating an excitation light 34 that penetrates inside the n-type silicon carbide epitaxial layer 2, and the size and position information of the defects can be obtained based on the position specifying mark.

From the PL images at steps S3 and S4, not only defects but also threading edge dislocations (TEDs) into which BPDs propagated from the n⁺-type silicon carbide substrate 1 have converted in the n-type low concentration buffer layer 20 can be detected, however, in the embodiment, only the size and position information of the defects are detected.

FIG. 5 is a cross-sectional view depicting defect detection from a PL image of the n⁻-type silicon carbide epitaxial layer in the method of manufacturing the silicon carbide semiconductor device according to the embodiment. As depicted in FIG. 5, at step S4, defects in the n⁻-type silicon carbide epitaxial layer 2 are detected using the excitation light 34 that penetrates inside the n-type silicon carbide epitaxial layer 2. Thus, the defect 32 from the n⁻-type silicon carbide epitaxial layer 2 is detected.

Steps S3 and S4 may be performed in reverse order where, first, the size and location information of defects in the n⁻-type silicon carbide epitaxial layer 2 may be detected by the PL image of the n⁻-type silicon carbide epitaxial layer 2, and then, defects from the n⁺-type buffer layer 20 to the n⁻-type silicon carbide epitaxial layer 2 may be detected by the PL image of the n⁺-type buffer layer 20.

Here, while the PL images are obtained twice (once each at steps S3 and S4), the PL images may be obtained more than twice. For example, when epitaxial layers are stacked by multistage epitaxial growth, the PL images may be obtained for each stage of epitaxial growth.

Next, defects from the n⁺-type silicon carbide substrate 1 and from the n-type low concentration buffer layer 20 are detected (step S5: third detecting process). In the process at step S5, a difference is obtained between the size and position information of the defects in the n⁻-type silicon carbide epitaxial layer 2 and in the n-type low concentration buffer layer 20 obtained at step S3 and the size and position information of defects in the n-type silicon carbide epitaxial layer 2 obtained at step S4. As a result, the size and position information of the defects in the n⁻-type silicon carbide epitaxial layer 2 is deleted, and the size and position information of the defects in the n⁻-type low concentration buffer layer 20 are detected.

Here, since the n-type low concentration buffer layer 20 is an epitaxial layer, defects from the n⁻-type low concentration buffer layer 20 are also present. However, since the n⁻-type low concentration buffer layer 20 is thinner as compared to the n⁻-type silicon carbide epitaxial layer 2 and the n⁺-type silicon carbide substrate 1, there are few defects from the n-type low concentration buffer layer 20. For this reason, the defects from the n⁻-type low concentration buffer layer 20 are treated the same as the defect 31 from the n⁺-type silicon carbide substrate 1. Therefore, only the size and position information of the defect 31 from the n⁺-type silicon carbide substrate 1 are obtained by the process at step S5.

Thus, only the size and position information of the defect 31 from the n⁺-type silicon carbide substrate 1 are detected, the defect 31 being a killer defect causing a significant decrease in the tolerance, reliability, and electrical characteristics of the silicon carbide semiconductor device, and the size and position information of the defect 32 from the n⁻-type silicon carbide epitaxial layer 2 are deleted, the defect 32 not being a killer defect.

Thus, the rate of conforming products can be improved by classifying the semiconductor chips 30 including the defect 31 from the n⁺-type silicon carbide substrate 1 as defective and by classifying the semiconductor chips 30 including only the defect 32 from the n-type silicon carbide epitaxial layer 2 as conforming.

For example, the PL images at steps S3 and S4 can be obtained as follows. In Example 1 of the embodiments, without changing the wavelength of the excitation light, a confocal point is adjusted to change the position for detecting defects in the semiconductor layer. In the PL measurement, the position at which the PL image can be obtained is determined by the position of the confocal point of the excitation light. Thus, at step S3, the confocal point of the excitation light when obtaining the PL image is set to be within the n⁻-type low concentration buffer layer 20, so that the excitation light 33 reaching the n⁻-type low concentration buffer layer is irradiated to obtain the PL image of the n-type low concentration buffer layer 20. At step S4, the confocal position of the excitation light when obtaining the PL image is set to be shallower and within the n⁻-type silicon carbide epitaxial layer 2, so that the excitation light 34 that penetrates inside the n⁻-type silicon carbide epitaxial layer 2 is irradiated to obtain the PL image of the n-type silicon carbide epitaxial layer 2.

In Example 2 of the embodiments, the position for detecting defects in the semiconductor layer is changed by changing the wavelength of the excitation light. In the PL measurement, when the wavelength of the excitation light is increased, a PL image at a deeper position can be obtained. Thus, at step S3, the wavelength of the excitation light when obtaining the PL image is adjusted, so that the excitation light 33 reaching the n-type low concentration buffer layer 20 is irradiated to obtain the PL image of the n-type low concentration buffer layer 20. At step S4, the wavelength of the excitation light when obtaining the PL image is adjusted to be shorter, so that the excitation light 34 reaching the inside of n-type silicon carbide epitaxial layer 2 is irradiated to obtain the PL image of n-type silicon carbide epitaxial layer 2. Specifically, at step S3, the defects in the n-type low concentration buffer layer 20 are detected by the excitation light 33 with a wavelength of 365 nm, and at step S4, the defects in the n⁻-type silicon carbide epitaxial layer 2 are detected by the excitation light 34 with a wavelength of 313 nm.

The wavelength is changed depending on the doping concentration and film thickness of the n-type low concentration buffer layer 20 and that of n-type silicon carbide epitaxial layer 2. The above wavelengths are for a case where the doping concentration of the n⁻-type low concentration buffer layer 20 is not more than 3×10¹⁷/cm³ and is at least three times the doping concentration of the n-type silicon carbide epitaxial layer 2 and the film thickness of the n⁻-type silicon carbide epitaxial layer 2 is not more than 70 μm.

Next, various processes are performed to form a predetermined device structure (for example, refer to FIG. 2) in each of the chip regions 51 of the semiconductor wafer 50 (step S6: forming process). At this time, formation of the device structure may be omitted for the chip regions 51 classified to be defective chips after the process at step S8 described below. Next, the semiconductor wafer 50 is cut (diced) along the dicing lines 52 (thick lines) to separate the chip regions 51 into the individual semiconductor chips 30 (SiC chips: refer to FIG. 1) (step S7: cutting process). Next, the semiconductor chips 30 that are candidates for conforming products are selected based on the information obtained in the process at step S5 (step S8: selecting process). Specifically, in the process at step S8, the semiconductor chips 30 free of the defect 31 from the n⁺-type silicon carbide substrate 1 are selected as candidates for conforming products.

Each of the semiconductor chips 30 selected as a candidate for a conforming product is then inspected for electrical characteristics such as on-voltage characteristics, withstand voltage characteristics, and leakage current characteristics, etc. by a general reliability test (step S9: inspecting process). In the process at step S9, various other tests may be performed to confirm or evaluate conditions that do not affect the withstand capacity and reliability. The process at step S9 and other tests may be performed after the process at step S7 but before the process at step S8, provided there is no problem in performing such tests in the state of the semiconductor wafer 50. Next, based on the results at step S9, the semiconductor chips 30 constituting conforming products (conforming chips) are selected based on the results at step S9 (step S10), thereby, completing the manufacture of the silicon carbide semiconductor device.

In the method of manufacturing of the silicon carbide semiconductor device according to the embodiments described, the processes at steps S9 and S10 may be omitted and the semiconductor chips 30 selected in the process at step S8 may be classified as conforming products. At step S6, when the n⁻-type high concentration region 5, the first p⁺-type base regions 3, the second p⁺-type base regions 4, and the n⁺-type regions 17 of the silicon carbide semiconductor device are formed, the n⁺-type regions 17 may be selectively formed in the n-type silicon carbide epitaxial layer 2 by ion implantation and an n-type epitaxial layer constituting the n-type high concentration region 5 may be grown by epitaxy, thereafter the first p⁺-type base regions 3 and the second p⁺-type base regions 4 may be selectively formed in the n-type high concentration region 5 before epitaxial growth of a p-type epitaxial layer constituting the p-type base layer 6.

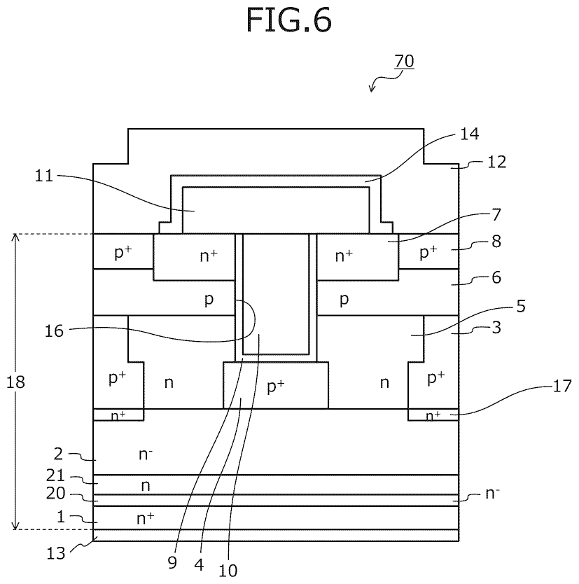

FIG. 6 is a cross-sectional view depicting another structure of the silicon carbide semiconductor device according to the embodiments. As depicted in FIG. 6, the trench MOSFET 70 may have an n-type transition layer 21 between the n-type low concentration buffer layer 20 and the n-type silicon carbide epitaxial layer 2.

The n-type transition layer 21 is thinner than and has a higher doping concentration than the n⁻-type low concentration buffer layer 20. Furthermore, the n-type transition layer 21 has a doping concentration lower than the doping concentration of the n⁺-type silicon carbide substrate 1. For example, the film thickness of the n-type transition layer 21 is in a range of 0.1 μm to 2 μm and preferably may be 1 μm or less while the doping concentration of the n-type transition layer 21 is 1×10¹⁸/cm³ or more but lower than the doping concentration of the n⁺-type silicon carbide substrate 1. The n-type transition layer 21 is a dislocation conversion layer converting a basal plane dislocation (BPD) into a threading edge dislocation (TED).

Even in this case, at step S3, the size and position information of defects in a region from the n⁻-type low concentration buffer layer 20 to the n-type silicon carbide epitaxial layer 2 are detected by the PL image of the n-type low concentration buffer layer 20; at step S4, the size and position information of defects in the n-type silicon carbide epitaxial layer 2 are detected by the PL image of the n⁻-type silicon carbide epitaxial layer 2; and at step S5, only the size and position information of the defect 31 originating from the n⁺-type silicon carbide substrate 1 is obtained.

Since the n-type transition layer 21 is thinner than the n⁻-type silicon carbide epitaxial layer 2, the n⁺-type silicon carbide substrate 1, and the n-type low concentration buffer layer 20, there are few defects from the n-type transition layer 21. Thus, a defect from the n-type transition layer 21 as well as a defect from the n-type low concentration buffer layer 20 are treated the same as the defect 31 from the n⁺-type silicon carbide substrate 1.

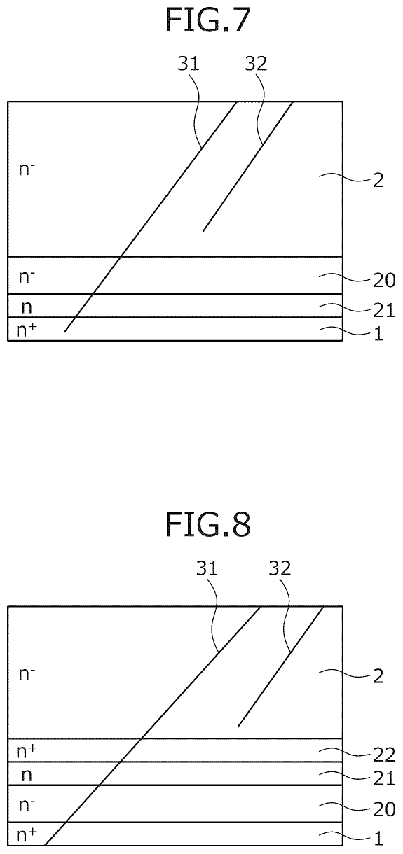

FIG. 7 is a partial cross-sectional view of a structure different from the configuration from the n⁺-type silicon carbide substrate 1 to the n-type silicon carbide epitaxial layer 2 in FIG. 6. FIG. 7 differs from FIG. 6 in that the n-type transition layer 21 is formed on the n⁺-type silicon carbide substrate 1, the n-type low concentration buffer layer 20 is formed on the n-type transition layer 21, and the n-type silicon carbide epitaxial layer 2 is formed on the n-type low concentration buffer layer 20. The doping concentration and thickness of each of the n⁺-type silicon carbide substrate 1, the n-type transition layer 21, the n-type low concentration buffer layer 20, and the n-type silicon carbide epitaxial layer 2 in FIG. 7 can be the same as those in FIG. 6.

FIG. 8 is a partial cross-sectional view of a structure further different from the configuration from the n⁺-type silicon carbide substrate 1 to the n-type silicon carbide epitaxial layer 2 in FIGS. 6 and 7. FIG. 8 differs from FIG. 6 in that an n⁺-type high concentration buffer layer (second buffer layer) 22 is further formed between the n-type transition layer 21 and the n⁻-type silicon carbide epitaxial layer 2. The doping concentration and thickness of each of the n⁺-type silicon carbide substrate 1, the n-type transition layer 21, the n-type low concentration buffer layer 20, and the n⁻-type silicon carbide epitaxial layer 2 in FIG. 8 may be the same as those in FIG. 6. When a current flows in the forward direction in pn junctions (pn junctions between the p-type base layer 6, the first and second p⁺-type base regions 3 and 4, the n-type high concentration region 5, and the n-type silicon carbide epitaxial layer 2) constituting main junctions, the n⁺-type high concentration buffer layer 22 has a function of capturing minority carriers (holes) generated at the interface of the pn junctions and eliminating the minority carriers by recombination with majority carriers (electrons) to thereby reduce the number of holes reaching the BPDs present deeper toward the n⁺-type silicon carbide substrate 1 than is the n⁺-type high concentration buffer layer 22. Accordingly, the growth of stacking faults over time due to the use of the SiC-MOSFET can be suppressed by providing the n⁺-type high concentration buffer layer 22.

In other words, the n⁺-type high concentration buffer layer 22 is also called a recombination promotion layer and suppresses the occurrence of stacking faults and increases in the area thereof by introducing a lifetime killer into high doping layers to promote the recombination of holes from the n-type silicon carbide epitaxial layer 2 and to control the concentration of holes reaching the n⁺-type silicon carbide semiconductor substrate 1. The n⁺-type high concentration buffer layer 22 has approximately a same doping concentration as the n⁺-type silicon carbide substrate 1, for example, 3×10¹⁸/cm³ or high, and preferably has a thickness of 3 μm to 10 μm.

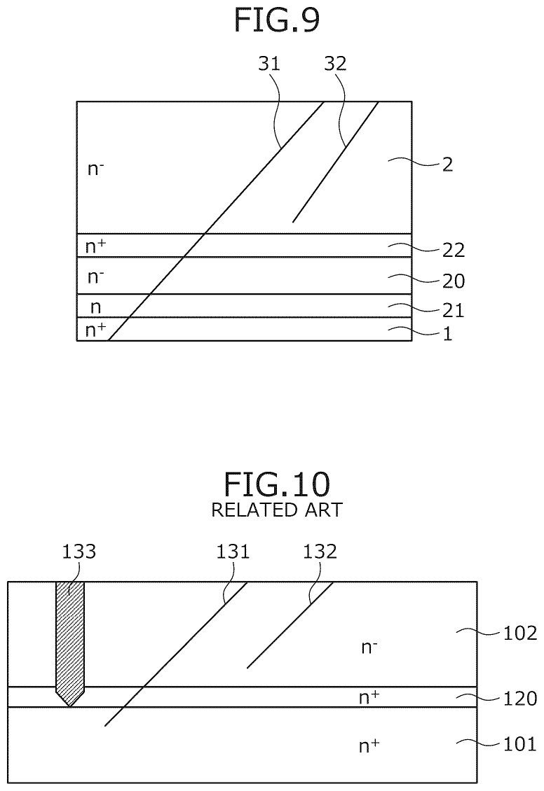

FIG. 9 is a partial cross-sectional view of a structure further different from the configuration from the n⁺-type silicon carbide substrate 1 to the n-type silicon carbide epitaxial layer 2 in FIGS. 6, 7, and 8. FIG. 9 differs from FIG. 8 in that the n-type transition layer 21 is formed on the n⁺-type silicon carbide substrate 1, the n⁻-type low concentration buffer layer 20 is formed on the n-type transition layer 21, the n⁺-type high concentration buffer layer 22 is formed on the n-type low concentration buffer layer 20, and the n-type silicon carbide epitaxial layer 2 is formed on the n⁺-type high concentration buffer layer 22. The doping concentration and thickness of each of the n⁺-type silicon carbide substrate 1, the n-type transition layer 21, the n⁻-type low concentration buffer layer 20, n⁺-type high concentration buffer layer 22, and n-type silicon carbide epitaxial layer 2 in FIG. 9 may be the same as those in FIG. 8.

The method of manufacturing a silicon carbide semiconductor device described in the embodiments can be realized by executing a previously prepared program on a computer such as a personal computer or a workstation, a database server, or a web server. The size and position information of the crystal defects obtained by this program or the process at step S3 is stored to a computer-readable recording medium such as a solid-state drive (SSD), a hard disk, a Blu-ray Disc (BD), a flexible disk, a USB flash memory, a CD-ROM, an MO, or a DVD and is executed by being read from the recording medium by a computer or a server.

This program may be a transmission medium that can be distributed via a network such as the Internet.

As described above, according to the embodiments, the size and position information of the defects in the n-type low concentration buffer layer are obtained from the difference between the detection result from the PL image of the n-type low concentration buffer layer and the detection result from the PL image of the n-type silicon carbide epitaxial layer. This allows the size and position information of only defects from the n⁺-type silicon carbide substrate, which are killer defects, to be detected. Thus, the rate of conforming products can be improved by classifying the semiconductor chips including the defects from the n⁺-type silicon carbide substrate as defective and by classifying the semiconductor chips including only the defects from the n-type silicon carbide epitaxial layer 2 as conforming.

In the foregoing, the invention may be variously modified within a range not departing from the spirit of the invention and in each embodiment described above, for example, dimensions and doping concentrations, etc. of each region are variously set according to necessary specifications. In the embodiments described above, while a trench gate vertical MOSFET is described as an example, the invention is further applicable to an insulated gate bipolar transistor (IGBT) and the like. In each embodiment, while a first conductivity type is assumed to be an n-type and a second conductivity type is assumed to be a p-type, the present invention is similarly implemented when the first conductivity type is the a p-type and the second conductivity type is an n-type.

According to the invention described above, the defects in the low concentration buffer layer are detected from a difference between a detection result from the PL image of the low concentration buffer layer and the detection result from the PL image of the epitaxial layer. As a result, only the size and position information of the defects from the silicon carbide substrate, the defects being killer defects, may be obtained. Thus, the semiconductor chips containing the defects from the silicon carbide substrate can be classified as defective while semiconductor chips containing only defects from the epitaxial layer can be classified as conforming, whereby the rate of conforming products can be improved.

According to a silicon carbide semiconductor device and a method of manufacturing a silicon carbide semiconductor device of the present invention, an effect is achieved in that only the chip regions containing defects attributable to the substrate can be removed as defective chips.

As described above, the silicon carbide semiconductor device and the method of manufacturing the silicon carbide semiconductor device according to the present invention are useful for power semiconductor devices that are used in power converting equipment such as inverters, power supply devices for various industrial machines, and automobile igniters, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A vertical silicon carbide semiconductor device formed in a semiconductor chip having two main surfaces opposite to each other, comprising:
a silicon carbide substrate;
a buffer layer that is an epitaxial layer on the silicon carbide substrate:
another epitaxial layer having a doping concentration in a range of 1×10¹⁵/cm³ to 1×10¹⁶/cm³ on the buffer layer; and
electrodes on each of the two main surfaces of the semiconductor chip, wherein
the buffer layer has a doping concentration that is higher than the doping concentration of the another epitaxial layer but not more than 3×10¹⁷/cm³, and
the silicon carbide semiconductor device is free of a defect that extends from the silicon carbide substrate to the another epitaxial layer.

2. The silicon carbide semiconductor device according to claim 1, further comprising a transition layer disposed between the silicon carbide substrate and the another epitaxial layer, the transition layer having a doping concentration between the doping concentration of the buffer layer and a doping concentration of the silicon carbide substrate.

3. The silicon carbide semiconductor device according to claim 2, wherein the transition layer is thinner than the buffer layer.

4. The silicon carbide semiconductor device according to claim 3, wherein the buffer layer is a first buffer layer, further comprising a second buffer layer disposed between the silicon carbide substrate and the another epitaxial layer, the second buffer layer having a doping concentration between the doping concentration of the transition layer and the doping concentration of the silicon carbide substrate.

5. The silicon carbide semiconductor device according to claim 4, wherein the second buffer layer is thicker than the first buffer layer.

6. A vertical silicon carbide semiconductor device formed in a semiconductor chip having two main surfaces opposite to each other, comprising:
a silicon carbide substrate;
a buffer layer that is an epitaxial layer on the silicon carbide substrate:
another epitaxial layer having a doping concentration in a range of 1×10¹⁵/cm³ to 1×10¹⁶/cm³ on the buffer layer; and
electrodes on each of two main surfaces of a semiconductor chip, wherein
the buffer layer has a doping concentration that is higher than the doping concentration of the another epitaxial layer but not more than 3×10¹⁷/cm³,
the silicon carbide semiconductor device is free of a first defect that extends from the silicon carbide substrate to the another epitaxial layer, and
the silicon carbide semiconductor device includes a second defect that is related to epitaxy growth, the second defect being provided in the another epitaxial layer generated during the epitaxy.

7. The silicon carbide semiconductor device according to claim 6, wherein the doping concentration of the buffer layer is not more than 3×10¹⁷/cm³.

8. The silicon carbide semiconductor device according to claim 6, further comprising a transition layer disposed between the buffer layer and the another epitaxial layer, the transition layer having a doping concentration that is higher than the doping concentration of the buffer layer.

9. A method of manufacturing a vertical silicon carbide semiconductor device having electrodes on each of two main surfaces of a semiconductor chip that includes a low concentration buffer layer and an epitaxial layer that are grown on a silicon carbide substrate by epitaxy, the method comprising:
as a pre-process, preparing a semiconductor wafer in which the low concentration buffer layer and the epitaxial layer are grown on the silicon carbide substrate by epitaxy;
as a first detecting process, using a photoluminescence (PL) image of the low concentration buffer layer to detect a first defect that extends from the silicon carbide substrate to the epitaxial layer and a second defect that is generated in the epitaxial layer during the epitaxy;
as a second detecting process, using a PL image of the epitaxial layer to detect the second defect;
as a third detecting process, detecting the first defect based on a difference between detection results of the first detecting process and the second detecting process;
as a forming process, forming a predetermined device structure in the semiconductor wafer;
as a cutting process, dicing the semiconductor wafer into a plurality of individual semiconductor chips after the forming process; and
as a selecting process, selecting from the plurality of semiconductor chips, one free of the first defect, based on a result of the third detecting process.

10. The method according to claim 9,
wherein the first detecting process includes obtaining the PL image of the low concentration buffer layer by setting a confocal position of an excitation light to be inside the low concentration buffer layer, the excitation light being used to obtain the PL image of the low concentration buffer layer, and
the second detecting process includes obtaining the PL image of the epitaxial layer by setting the confocal position of the excitation light to be inside the epitaxial layer, the excitation light being used to obtain the PL image of the epitaxial layer.

11. The method according to claim 9, wherein
the first detecting process includes obtaining the PL image of the low concentration buffer layer by adjusting a wavelength of an excitation light used to obtain the PL image of the low concentration buffer layer, and
the second detecting process includes obtaining the PL image of the epitaxial layer by adjusting the wavelength of the excitation light used to obtain the PL image of the epitaxial layer, the wavelength being adjusted to be shorter than the wavelength used in the first detecting process.
